(19) United States
(12) Patent Application Publication
(10) Pub. No.: US 2023/0389363 A1
(43) Pub. Date: Nov. 30, 2023

(54) DISPLAY DEVICE AND METHOD FOR MANUFACTURING THE SAME

(71) Applicant: Samsung Display Co., Ltd., Yongin-si (KR)

(72) Inventors: EUNGGYU LEE, Cheonan-si (KR); SOO-HYE RYU, Yongin-si (KR); JINSU LEE, Suwon-si (KR)

(21) Appl. No.: 18/114,536

(22) Filed: Feb. 27, 2023

(30) Foreign Application Priority Data
May 27, 2022 (KR) 10-2022-0065561

(51) Int. Cl. H10K 59/122; H10K 59/12; H10K 59/80

(52) U.S. Cl. CPC H10K 59/122; H10K 59/1201; H10K 59/873; H10K 59/877; H10K 59/8791; H10K 59/8792

(57) ABSTRACT

A display device includes: a substrate, a light emitting element disposed on the substrate, an encapsulation layer disposed on the light emitting element, a bank layer disposed on the encapsulation layer, defining an opening overlapping the light emitting element, and including a first base layer and a plurality of first scattering particles dispersed in the first base layer, and an anti-reflection layer disposed inside the opening.

This application claims priority to Korean Patent Application No. 10-2022-0065561, filed on May 27, 2022, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a display device providing visual information and a method for manufacturing the same.

### 2. Description of the Related Art

With the development of information technology, the importance of a display device, which is a connection medium between a user and information, has been highlighted. For example, the use of the display device such as liquid crystal display device (“LCD”), organic light emitting display device (“OLED”), plasma display device (“PDP”), quantum dot display device or the like is increasing.

Meanwhile, since the display device includes lines and electrodes including metal, external light incident on the display device may be reflected from the lines and the electrodes. In order to prevent reflection by external light, the display device generally includes a polarizer. However, although the polarizer may prevent reflection by external light, the light efficiency of the display device may be reduced due to the polarizer.

### SUMMARY

Embodiments provide a display device with improved display quality.

Embodiments provide a method for manufacturing the display device.

A display device according to embodiments of the present disclosure includes a substrate, a light emitting element disposed on the substrate, an encapsulation layer disposed on the light emitting element, a bank layer disposed on the encapsulation layer, defining an opening overlapping the light emitting element, and including a first base layer and a plurality of first scattering particles dispersed in the first base layer, and an anti-reflection layer disposed inside the opening.

In an embodiment, each of the first scattering particles may include an inorganic material.

In an embodiment, the inorganic material may include at least one selected from a group consisting of titanium oxide (TiO₂), aluminum oxide (Al₂O₃), zirconium oxide (ZrO₂), and silicon oxide (SiO₂).

In an embodiment, the first base layer may include an organic material or an inorganic material.

In an embodiment, the first base layer may further include at least one selected from a group consisting of a carbon black, a black pigment, and a black dye.

In an embodiment, the first base layer may further include at least one selected from a group consisting of an orange pigment, a violet pigment, and a blue pigment.

In an embodiment, a refractive index of the bank layer may be smaller than a refractive index of the anti-reflection layer.

In an embodiment, the refractive index of the bank layer may be about 1.2 to about 1.4.

In an embodiment, the refractive index of the anti-reflection layer may be about 1.5 to about 1.7.

In an embodiment, the anti-reflection layer may include an inorganic material or an organic material.

In an embodiment, the anti-reflection layer may include at least one selected from a group consisting of a pigment, a binder, and a monomer.

In an embodiment, the display device may further include a low refractive index layer disposed inside the opening. The anti-reflection layer may be disposed on the low refractive index layer.

In an embodiment, the low refractive index layer may be monolithic with the bank layer.

In an embodiment, the low refractive index layer may include a second base layer and a plurality of second scattering particles dispersed in the second base layer.

In an embodiment, the second base layer may include an organic material or an inorganic material, and each of the second scattering particles may include an inorganic material.

In an embodiment, the display device may further include a capping layer disposed on the light emitting element and a light absorption layer disposed between the capping layer and the encapsulation layer and including an inorganic material.

A method for manufacturing a display device according to embodiments of the present disclosure includes forming a light emitting element on a substrate, forming an encapsulation layer on the light emitting element, forming a bank layer defining an opening overlapping the light emitting element and including a first base layer and a plurality of first scattering particles dispersed in the first base layer on encapsulation layer, and forming an anti-reflection layer inside the opening through an inkjet printing process.

In an embodiment, the first base layer may include an organic material or an inorganic material, and each of the first scattering particles may include an inorganic material.

In an embodiment, the first base layer may further include at least one selected from a group consisting of a carbon black, a black pigment, and a black dye.

In an embodiment, a refractive index of the bank layer may be smaller than a refractive index of the anti-reflection layer.

A display device according to an embodiment of the present disclosure may include a bank layer including a plurality of first scattering particles and an anti-reflection layer disposed inside an opening of the bank layer. A refractive index of the bank layer may be smaller than a refractive index of the anti-reflection layer. Accordingly, total reflection of the light incident on the bank layer among lights emitted from a light emitting element may easily occur. That is, the light efficiency of the display device may be effectively improved.

In a method of manufacturing the display device according to an embodiment of the present disclosure, the anti-reflection layer may be formed through an inkjet printing process. Accordingly, the process cost of the display device may be effectively reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view taken along line I-I′ of FIG. 1.

FIG. 3 is an enlarged cross-sectional view of portion “A” of FIG. 2.

FIGS. 4, 5, 6, and 7 are cross-sectional views illustrating a method of manufacturing the display device of FIG. 2.

FIG. 8 is a cross-sectional view illustrating a display device according to another embodiment.

FIG. 9 is a cross-sectional view illustrating a display device according to still another embodiment.

FIG. 10 is a cross-sectional view illustrating a display device according to still another embodiment.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, a display device according to embodiments of the present disclosure will be explained in detail with reference to the accompanying drawings. The same reference numerals are used for the same components in the drawings, and redundant descriptions of the same components will be omitted.

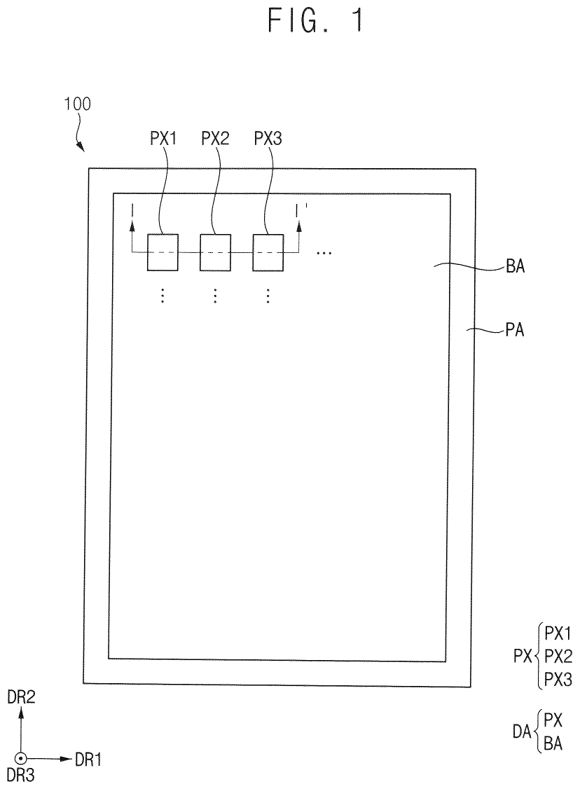

FIG. 1 is a plan view illustrating a display device according to an embodiment.

Referring to FIG. 1, a display device 100 according to an embodiment may include a display area DA and a peripheral area PA. The display area DA may mean an area displaying an image. The peripheral area PA may mean an area that does not display an image. The peripheral area PA may be positioned around the display area DA. For example, the peripheral area PA may entirely surround the display area DA.

The display area DA may include a plurality of pixel areas PX and a light blocking area BA. Each of the pixel areas PX may include a first pixel area PX1, a second pixel area PX2, and a third pixel area PX3.

Each of the first pixel area PX1, the second pixel area PX2, and the third pixel area PX3 may refer to an area in which light emitted from a light emitting element is emitted to an outside of the display device 100. For example, the first pixel area PX1 may emit a first light, the second pixel area PX2 may emit a second light, and the third pixel area PX3 may emit a third light. In an embodiment, the first light may be red light, the second light may be green light, and the third light may be blue light. However, the present disclosure is not limited thereto. For example, the pixel areas PX may be combined to emit yellow, cyan, and magenta lights in another embodiment.

The pixel areas PX may emit light of four or more colors. For example, the pixel areas PX may be combined to further emit at least one of yellow, cyan, and magenta lights in addition to red, green, and blue lights. In addition, the pixel areas PX may be combined to further emit white light.

In a plan view, each of the first pixel area PX1, the second pixel area PX2, and the third pixel area PX3 may be repeatedly arranged in a row direction and a column direction. Specifically, each of the first pixel area PX1, the second pixel area PX2, and the third pixel area PX3 may be repeatedly arranged in a first direction DR1 and a second direction DR2 in a plan view. The second direction DR2 may be perpendicular to the first direction DR1. A third direction DR3 is perpendicular to the first direction DR1 and the second direction DR2. The “plan view” is a view in the third direction DR3.

Each of the first pixel area PX1, the second pixel area PX2, and the third pixel area PX3 may have a triangular planar shape, a rectangular planar shape, a circular planar shape, a track-type planar shape, an elliptical planar shape, or the like. In an embodiment, each of the first pixel area PX1, the second pixel area PX2, and the third pixel area PX3 may have a rectangular planar shape. However, the present disclosure is not limited thereto, and each of the first pixel area PX1, the second pixel area PX2, and the third pixel area PX3 may have a different planar shape in another embodiment.

The light blocking area BA may be positioned between the first pixel area PX1, the second pixel area PX2, and the third pixel area PX3. For example, in a plan view, the light blocking area BA may surround the first pixel area PX1, the second pixel area PX2, and the third pixel area PX3. The light blocking area BA may not emit light.

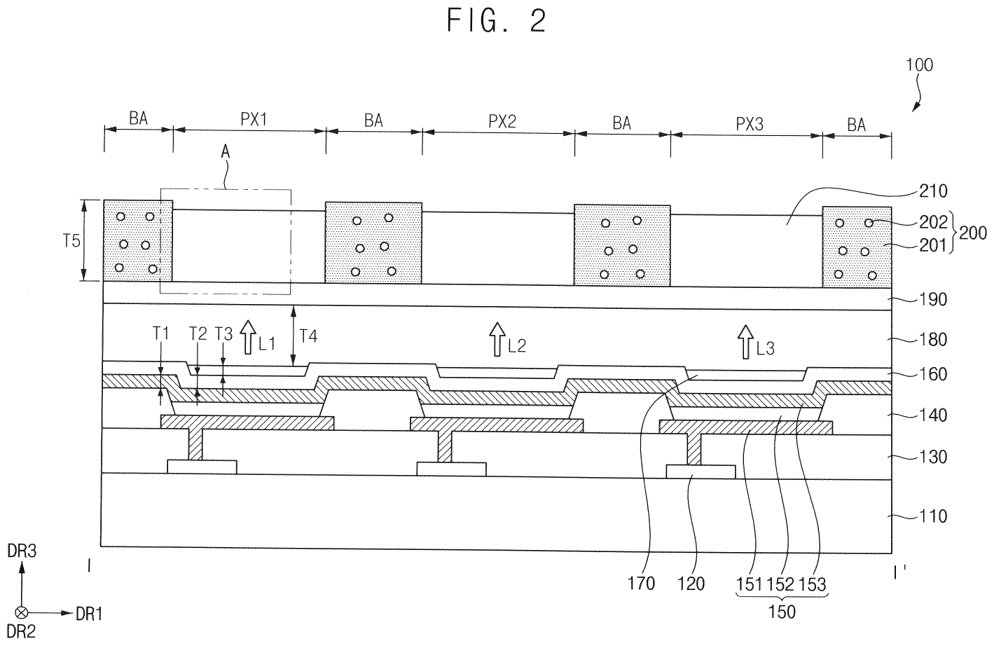

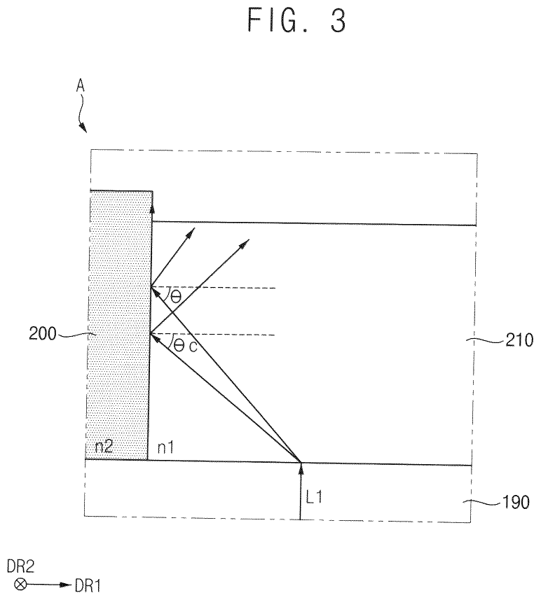

FIG. 2 is a cross-sectional view taken along line I-I′ of FIG. 1. FIG. 3 is an enlarged cross-sectional view of portion “A” of FIG. 2.

Referring to FIGS. 2 and 3, the display device 100 according to an embodiment may include a substrate 110, a transistor 120, an insulating structure 130, a pixel defining layer 140, a light emitting element 150, a capping layer 160, alight absorption layer 170, an encapsulation layer 180, a sensing layer 190, a bank layer 200, and an anti-reflection layer 210. Here, the light emitting element 150 may include a lower electrode 151, a light emitting layer 152, and an upper electrode 153.

The substrate 110 may include a transparent material or an opaque material. The substrate 110 may be formed of or include a transparent resin substrate. A polyimide substrate is an example of the said transparent resin substrate. In this case, the polyimide substrate may include a first organic layer, a first barrier layer, a second organic layer, or the like. Alternatively, the substrate 110 may be a quartz substrate, a synthetic quartz substrate, a calcium fluoride substrate, a fluorine-doped quartz substrate, a soda-lime substrate, a non-alkali glass substrate, or the like. These may be used alone or in combination with each other.

The transistor 120 may be disposed on the substrate 110. For example, the transistor 120 may include amorphous silicon, polycrystalline silicon, or a metal oxide semiconductor.

The metal oxide semiconductor may include a binary compound (ABₓ), a ternary compound (ABₓC_{y}), a quaternary compound (ABₓC_{y}D_{z}), or the like, containing indium (In), zinc (Zn), gallium (Ga), tin (Sn), titanium (Ti), aluminum (Al), hafnium (Hf), zirconium (Zr), magnesium (Mg), or the like. For example, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), and indium tin oxide. (“ITO”), indium zinc tin oxide (“IZTO”), indium gallium zinc oxide (“IGZO”), or the like. These may be used alone or in combination with each other.

The insulating structure 130 may be disposed on the substrate 110. The insulating structure 130 may cover the transistor 120. The insulating structure 130 may include at least one inorganic insulating layer and at least one organic insulating layer. For example, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), or the like. In addition, the organic insulating layer includes a photoresist, a polyacryl-based resin, a polyimide-based resin, a polyamide-based resin, a siloxane-based resin, an acrylic resin, an epoxy-based resin, or the like. Each of these may be used alone or in combination with each other.

The lower electrode 151 may be disposed in each of the first, second, and third pixel areas PX1, PX2, and PX3 on the insulating structure 130. The lower electrode 151 may be connected to the transistor 120 through a contact hole formed by removing a portion of the insulating structure 130. For example, the lower electrode 151 may include a metal, an alloy, a metal nitride, a conductive metal oxide, a transparent conductive material, or the like. These may be used alone or in combination with each other. For example, the lower electrode 151 may act as an anode.

The pixel defining layer 140 may be disposed in the light blocking area BA on the insulating structure 130 and the lower electrode 151. The pixel defining layer 140 may cover opposite sides of the lower electrode 151 and expose an upper surface of the lower electrode 151 in a plan view. The pixel defining layer 140 may include an organic material and/or an inorganic material. In an embodiment, the pixel defining layer 140 may include an organic material. For example, the pixel defining layer 140 may include a photoresist, a polyacrylic resin, a polyimide-based resin, a polyamide-based resin, a siloxane-based resin, an acrylic resin, an epoxy-based resin, or the like. These may be used alone or in combination with each other.

The light emitting layer 152 may be disposed in each of the first, second, and third pixel areas PX1, PX2, and PX3 on the lower electrode 151. For example, holes provided from the lower electrode 151 and electrons provided from the upper electrode 153 combine in the light emitting layer 152 to form excitons, and as the excitons change from an excited state to a ground state, the light emitting layer 152 may emit light.

The light emitting layer 152 may emit light having a specific color (e.g., red, green, and blue). In an embodiment, the light emitting layer 152 disposed in the first pixel area PX1 emits a first light L1, and the light emitting layer 152 disposed in the second pixel area PX2 emits a second light L2, and the light emitting layer 152 disposed in the third pixel area PX3 may emit a third light L3. For example, the first light L1 may be red light, the second light L2 may be green light, and the third light L3 may be blue light. However, the present disclosure is not limited thereto.

The upper electrode 153 may be disposed on the light emitting layer 152 and the pixel defining layer 140. For example, the upper electrode 153 may include a metal, an alloy, a metal nitride, a conductive metal oxide, a transparent conductive material, or the like. These may be used alone or in combination with each other. For example, the upper electrode 153 may act as a cathode.

Accordingly, the light emitting element 150 including the lower electrode 151, the light emitting layer 152, and the upper electrode 153 may be disposed on the substrate 110. The light emitting element 150 may be disposed in each of the first pixel area PX1, the second pixel area PX2, and the third pixel area PX3. The light emitting element 150 may be electrically connected to the transistor 120.

The capping layer 160 may be disposed on the upper electrode 153. The capping layer 160 may be entirely disposed on the upper electrode 153. The capping layer 160 may function to protect the upper electrode 153. For example, the capping layer 160 may include an organic material and/or an inorganic material.

The light absorption layer 170 may be disposed in each of the first, second, and third pixel areas PX1, PX2, and PX3 on the capping layer 160. The light absorption layer 170 may absorb external light. The light absorption layer 170 may include an inorganic material. For example, the inorganic material may include ytterbium oxide (Yb₂O₃), silicon dioxide (SiO₂), titanium dioxide (TiO₂), bismuth oxide (Bi₂O₃), or the like. These may be used alone or in combination with each other. In another embodiment, the light absorption layer 170 may be disposed to continuously extend on the capping layer 160.

The encapsulation layer 180 may be disposed on the capping layer 160 and the light absorption layer 170. The encapsulation layer 180 may prevent impurities, moisture, and the like from penetrating into the light emitting element 150 from an outside. The encapsulation layer 180 may include at least one inorganic encapsulation layer and at least one organic encapsulation layer. For example, the inorganic encapsulation layer may include silicon oxide, silicon nitride, silicon oxynitride, or the like, and the organic encapsulation layer may include a cured polymer such as polyacrylate.

The sensing layer 190 may be disposed on the encapsulation layer 180. A plurality of sensing electrodes may be formed in the sensing layer 190, and a user's touch may be sensed.

The bank layer 200 may be disposed in the light blocking area BA on the sensing layer 190. A space for accommodating an ink composition may be formed in the bank layer 200 in the process of forming the anti-reflection layer 210. In other words, the bank layer 200 may define openings overlapping the first, second, and third pixel areas PX1, PX2, and PX3, respectively, and exposing a portion of the sensing layer 190 in a plan view. Accordingly, in a plan view, the bank layer 200 may have a grid shape or a matrix shape.

In an embodiment, the bank layer 200 may include a first base layer 201 and a plurality of first scattering particles 202 dispersed in the first base layer 201. As the bank layer 200 includes the first scattering particles 202, the refractive index of the bank layer 200 may be relatively small.

The first base layer 201 may include an inorganic material and/or an organic material. For example, the organic material may include a photoresist, a polyacrylic resin, a polyimide-based resin, a polyamide-based resin, a siloxane-based resin, an acrylic resin, an epoxy-based resin, or the like. These may be used alone or in combination with each other.

The first base layer 201 may further include a light blocking material so that the bank layer 200 serves as a black matrix. In an embodiment, the first base layer 201 may further include a light blocking material such as a black pigment, a black dye, or carbon black. These may be used alone or in combination with each other. In another embodiment, the first base layer 201 may further include a colorant. For example, the colorant may include an orange pigment, a violet pigment, a blue pigment, or the like. These may be used alone or in combination with each other.

Each of the first scattering particles 202 may include an inorganic material. For example, the inorganic material may include titanium oxide (TiO₂), aluminum oxide (Al₂O₃), zirconium oxide (ZrO₂), silicon oxide (SiO₂), or the like. These may be used alone or in combination with each other.

The anti-reflection layer 210 may be disposed in each of the first, second, and third pixel areas PX1, PX2, and PX3 on the sensing layer 190. Specifically, the anti-reflection layer 210 may be disposed inside the opening of the bank layer 200. As the display device 100 includes the anti-reflection layer 210, the display device 100 may not include a polarizer. That is, the anti-reflection layer 210 may perform the function of the polarizer. In other words, the anti-reflection layer 210 may reduce reflection by external light.

The anti-reflection layer 210 may include an inorganic material and/or an organic material. In an embodiment, the anti-reflection layer 210 may include an organic material. For example, the anti-reflection layer 210 may include an organic material such as a photoresist, polyacrylic resin, polyimide-based resin, polyamide-based resin, siloxane-based resin, acrylic resin, epoxy-based resin, or the like. These may be used alone or in combination with each other.

Specifically, the anti-reflection layer 210 may include a photopolymerization initiator, a monomer, a binder, a dispersant, a pigment, a solvent, a photoresist, or the like. These may be used alone or in combination with each other. For example, the pigment may include an organic pigment, a red pigment, a green pigment, a blue pigment, or the like. These may be used alone or in combination with each other. Accordingly, the anti-reflection layer 210 may have a gray color.

Here, the organic pigment may be a known pigment formed of or include an organic material and commonly used among pigments having a black color. In addition, the red pigment, the green pigment, and the blue pigment may be known pigments commonly used among pigments having red, green, and blue colors, respectively.

The refractive index of the anti-reflection layer 210 may be changed according to the content of the monomer and the binder. In addition, the refractive index of the anti-reflection layer 210 may be changed according to the type of the pigment.

The refractive index n₂ of the bank layer 200 may be smaller than the refractive index n₁ of the anti-reflection layer 210. In an embodiment, the refractive index n₂ of the bank layer 200 may be about 1.2 to about 1.4. In addition, the refractive index n₁ of the anti-reflection layer 210 may be about 1.5 to about 1.7. Accordingly, total reflection of the light incident on the bank layer 200 among lights (e.g., the first light L1, the second light L2, and the third light L3) emitted from the light emitting element 150 may easily occur.

Among the lights emitted from the light emitting element 150, the light incident on the bank layer 200 (e.g., the first light L1) may be totally reflected due to a difference between the refractive index n2 of the bank layer 200 and the refractive index n1 of the anti-reflection layer 210. In the present invention, total reflection may occur only when the refractive index n2 of the bank layer 200 is smaller than the refractive index n1 of the anti-reflection layer 210. As the difference between the refractive index n2 of the bank layer 200 and the refractive index n1 of the anti-reflection layer 210 increases, total reflection of the light incident on the bank layer 200 may easily occur.

For example, when the refractive index n₂ of the bank layer 200 is about 1.17 and each of the first scattering particles 202 of the bank layer 200 includes silicon oxide, the total reflection critical angle θ_{c} of the light incident on the bank layer 200 may be about 42 degrees. In this case, when the incident angle θ of the light incident on the bank layer 200 exceeds the total reflection critical angle θ_{c}, the light may be totally reflected by the bank layer 200.

The display device 100 according to an embodiment of the present disclosure may include the bank layer 200 including the plurality of first scattering particles 202 and the anti-reflection layer 210 disposed inside the opening of the bank layer 200. The refractive index of the bank layer 200 may be smaller than the refractive index of the anti-reflection layer 210. Accordingly, total reflection of the light incident on the bank layer 200 among lights emitted from the light emitting element 150 may easily occur. That is, the light efficiency of the display device 100 may be effectively improved.

However, although the display device 100 of the present disclosure is described by limiting an organic light emitting display device (OLED), the configuration of the present disclosure is not limited thereto. In other embodiments, the display device 1000 may include a liquid crystal display device (LCD), a field emission display device (“FED”), a plasma display device (PDP), an electrophoretic display device (“EPD”), an inorganic light emitting display device (“ILED”), or a quantum dot display device.

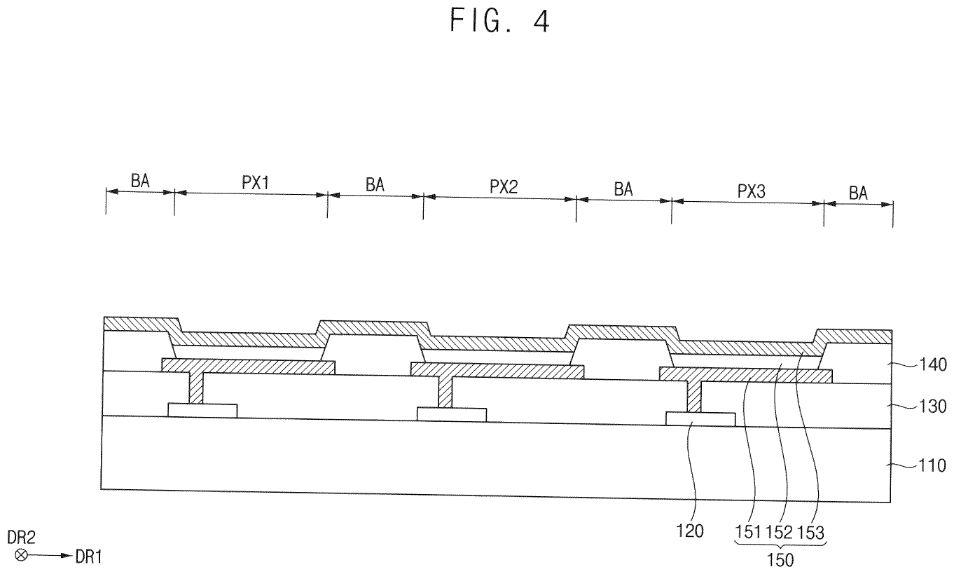

FIGS. 4, 5, 6, and 7 are cross-sectional views illustrating a method of manufacturing the display device of FIG. 2.

Referring to FIG. 4, the transistor 120 may be formed on a substrate 110. The substrate 110 may include a transparent material or an opaque material. For example, the substrate 110 may be formed of or include a transparent resin substrate. For example, the transistor 120 may be formed to include amorphous silicon, crystalline silicon, a metal oxide semiconductor, or the like.

The insulating structure 130 may be formed on the substrate 110. The insulating structure 130 may cover the transistor 120. For example, the insulating structure 130 may be formed to include at least one inorganic insulating layer and at least one organic insulating layer.

The lower electrode 151 may be formed in each of the first, second, and third pixel areas PX1, PX2, and PX3 on the insulating structure 130. The lower electrode 151 may be connected to the transistor 120 through a contact hole formed by removing a portion of the insulating structure 130. For example, the lower electrode 151 may be formed to include a metal, an alloy, a metal nitride, a conductive metal oxide, a transparent conductive material, or the like.

The pixel defining layer 140 may be formed in the light blocking area BA on the insulating structure 130 and the lower electrode 151. The pixel defining layer 140 may define an opening exposing a portion of the upper surface of the lower electrode 151 in a plan view. The pixel defining layer 140 may be formed to include an organic material and/or an inorganic material.

The light emitting layer 152 may be formed in each of the first, second, and third pixel areas PX1, PX2, and PX3 on the lower electrode 151. Specifically, the light emitting layer 152 may be formed inside the opening of the pixel defining layer 140. For example, the light emitting layer 152 may be formed to include a low molecular weight organic compound and/or a high molecular weight organic compound.

The upper electrode 153 may be formed on the light emitting layer 152 and the pixel defining layer 140. The upper electrode 153 may be entirely formed in the first pixel area PX1, the second pixel area PX2, the third pixel area PX3, and the light blocking area BA. For example, the upper electrode 153 may be formed to include a metal, an alloy, a metal nitride, a conductive metal oxide, a transparent conductive material, or the like.

Accordingly, the light emitting element 150 including the lower electrode 151, the light emitting layer 152, and the upper electrode 153 may be formed in each of the first to third pixel areas PX1, PX2, and PX3 on the substrate 110.

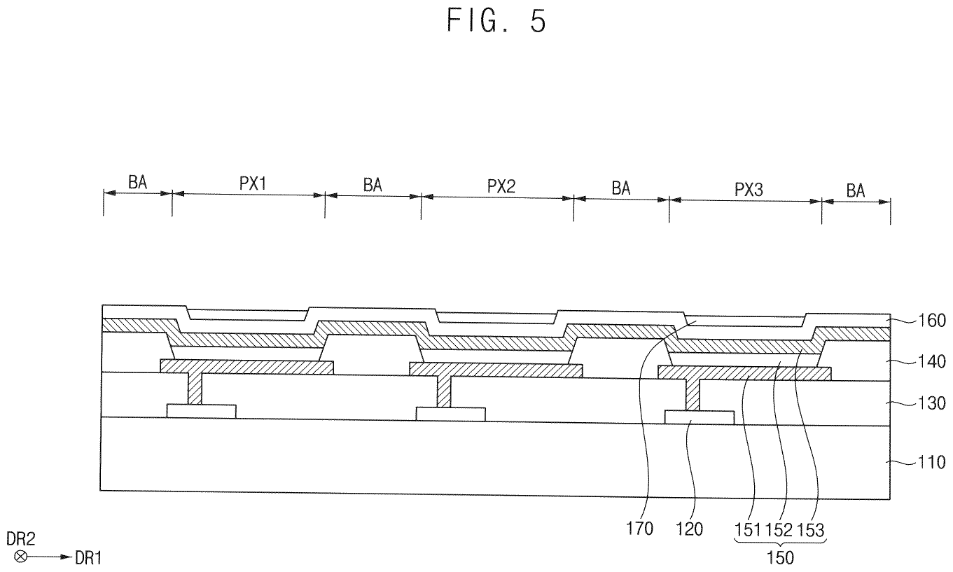

Referring to FIG. 5, the capping layer 160 may be formed on the upper electrode 153. The capping layer 160 may be entirely formed on the upper electrode 153. For example, the capping layer 160 may be formed to include an inorganic material and/or an organic material.

The light absorption layer 170 may be formed in each of the first, second, and third pixel areas PX1, PX2, and PX3 on the capping layer 160. For example, the light absorption layer 170 may be formed to include an inorganic material.

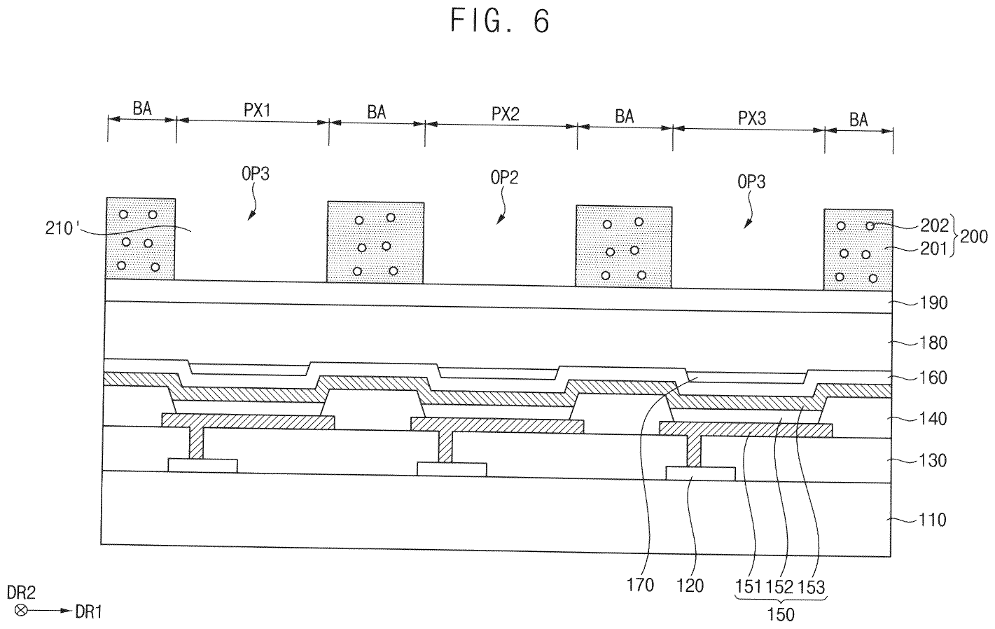

Referring to FIG. 6, the encapsulation layer 180 may be formed on the capping layer 160 and the light absorption layer 170. The encapsulation layer 180 may be entirely formed in the first pixel area PX1, the second pixel area PX2, the third pixel area PX3, and the light blocking area BA. For example, the encapsulation layer 180 may be formed to include an inorganic material and an organic material.

The sensing layer 190 may be formed on the encapsulation layer 180. The sensing layer 190 may be entirely formed in the first pixel area PX1, the second pixel area PX2, the third pixel area PX3, and the light blocking area BA. A plurality of sensing electrodes may be formed in the sensing layer 190.

The bank layer 200 may be formed in the light blocking area BA on the sensing layer 190. The bank layer 200 may define a first opening OP1 overlapping the first pixel area PX1, a second opening OP2 overlapping the second pixel area PX2, and a third opening OP3 overlapping a third pixel area PX3 in a plan view. Each of the first, second, and third openings OP1, OP2, and OP3 may expose a portion of the sensing layer 190 in a plan view. The first, second, and third openings OP1, OP2, and OP3 may receive an ink composition during a process of forming the anti-reflection layer (e.g., the anti-reflection layer 210 of FIG. 2).

The bank layer 200 may include the first base layer 201 and the plurality of first scattering particles 202 dispersed in the first base layer 201. For example, the first base layer 201 may be formed to include an organic material including a black pigment, a black dye, a carbon black, or the like. For example, each of the first scattering particles 202 may be formed to include an inorganic material.

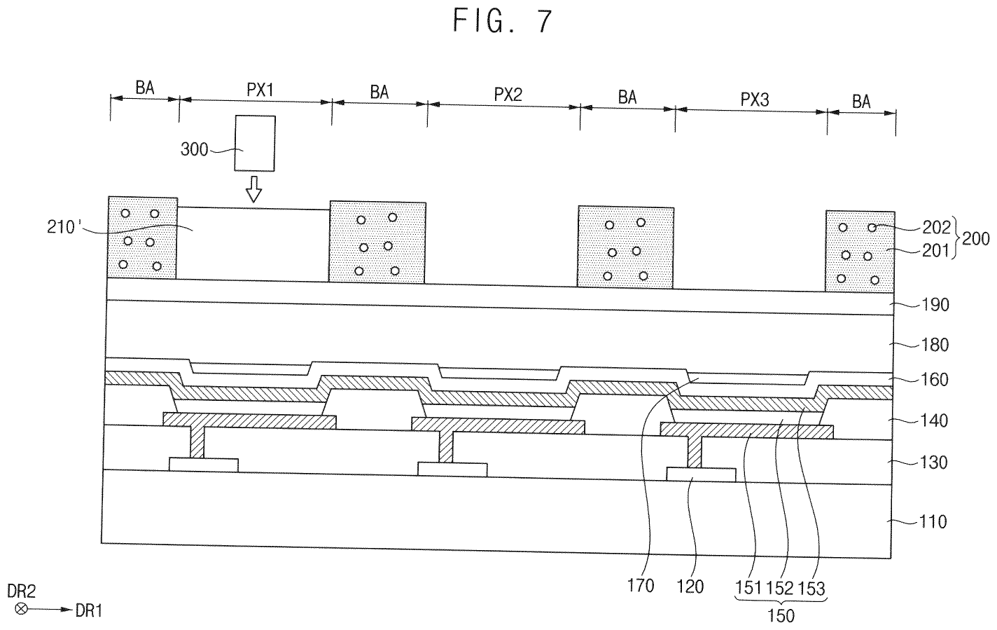

Referring to FIGS. 2 and 7, in an embodiment, the anti-reflection layer 210 may be formed through an inkjet printing process. Accordingly, the process cost of the display device 100 may be effectively reduced.

For example, the inkjet apparatus 300 may drop the ink composition onto the first opening OP1. Accordingly, the preliminary anti-reflection layer 201′ may be formed in the first pixel area PX1. Here, the ink composition may be a material forming the anti-reflection layer 210.

The inkjet apparatus 300 may repeatedly drip the ink composition onto the first opening OP1 to form the anti-reflection layer 210. In addition, the inkjet apparatus 300 may repeatedly drop the ink composition onto the second opening OP2 to form the anti-reflection layer 210. In addition, the inkjet apparatus 300 may repeatedly drop the ink composition onto the third opening OP3 to form the anti-reflection layer 210.

Accordingly, the display device 100 illustrated in FIG. 2 may be manufactured.

Hereinafter, the effect of the present invention will be described with reference to FIG. 2 again.

First, the reflectance of the bank layer 200 according to the change in a thickness T5 of the bank layer 200 in the third direction was measured. The reflectance of the bank layer 200 is proportional to the refractive index of the bank layer 200. The bank layer 200 satisfying Examples 1, 2, and 3 was formed to include carbon black and scattering particles including silicon oxide (SiO₂) were added to the bank layer 200. On the other hand, the scattering particles were not added to the bank layer 200 satisfying Comparative Examples 1, 2, and 3.

As a result, referring to Table 1 below, that the reflectance of the bank layer 200 satisfying the Example 1 is about 34 percentages (%) of the reflectance of the bank layer 200 satisfying the Comparative Example 1 may be confirmed. That the reflectance of the bank layer 200 satisfying the Example 2 is about 26% of the reflectance of the bank layer 200 satisfying the Comparative Example 2 may be confirmed. That the reflectance of the bank layer 200 satisfying the Example 3 is about 22 of the reflectance of the bank layer 200 satisfying the Comparative Example 3 may be confirmed. That is, that the bank layer 200 satisfying the Examples 1, 2, and 3 has a relatively smaller reflectance than the bank layer 200 satisfying the Comparative Examples 1, 2, and 3 may be confirmed. In other words, the bank layer 200 satisfying the Examples 1, 2, and 3 may have a relatively smaller refractive index than the bank layer 200 satisfying the Comparative Examples 1, 2, and 3.

TABLE 1

| | Thickness T5 | Reflectance of | Refractive |
|---|---|---|---|
| | of the bank layer | the bank layer | index of the |
| | (micrometers: μm) | (%) | bank layer |
| Example 1 | 1 | 1.49 | — |
| Example 2 | 2 | 1.50 | 1.17 |
| Example 3 | 3 | 1.45 | — |
| Comparative | 1 | 2.26 | — |
| Example 1 | | | |
| Comparative | 2 | 2.02 | — |
| Example 2 | | | |
| Comparative | 3 | 1.86 | — |
| Example 3 | | | |

Next, referring to Table 2 below, the luminance and the external light reflectance of the display device 100 according to changes in a thickness T1 of the upper electrode 153, a thickness T2 of the capping layer 160, a thickness T3 of the light absorption layer 170, a thickness T4 of the encapsulation layer 180, and the refractive index of the encapsulation layer 180 were measured.

TABLE 2

| | | | | | Refrac- |
|---|---|---|---|---|---|
| | Thickness | | Thickness | Thickness | tive |
| | T1 of the | Thickness | T3 of the | T4 of the | index |
| | upper | T2 of the | light | encap- | of the |
| | electrode | capping | absorption | sulation | encap- |
| | (angstroms: | layer | layer | layer | sulation |
| | Å) | (Å) | (Å) | (Å) | layer |
| Example 4 | 130 | 300 | 100 | 1,200 | 1.48 |
| Comparative | 130 | 300 | 100 | 1,400 | 1.48 |
| Example 4 | | | | | |
| Comparative | 105 | 300 | 100 | 1,400 | 1.48 |
| Example 5 | | | | | |
| Comparative | 130 | 600 | 100 | 1,400 | 1.89 |
| Example 6 | | | | | |

As a result, referring to Table 3 below, that the luminance of the display device 100 satisfying the Example 4 is greater than the luminance of the display device 100 satisfying Comparative Examples 4, 5, and 6 may be confirmed. In addition, that the external light reflectance of the display device 100 satisfying the Example 4 is smaller than the external light reflectance of the display device 100 satisfying the Comparative Examples 4, 5, and 6 may be confirmed. That is, when the Example 4 is satisfied, that the light efficiency of the display device 100 is improved may be confirmed

TABLE 3

| | | External light |
|---|---|---|
| | Luminance (nit) | reflectance (%) |
| Example 4 | 59.90 | 9.02 |
| Comparative Example 4 | 59.37 | 9.15 |
| Comparative Example 5 | 55.58 | 9.54 |
| Comparative Example 6 | 56.02 | 9.83 |

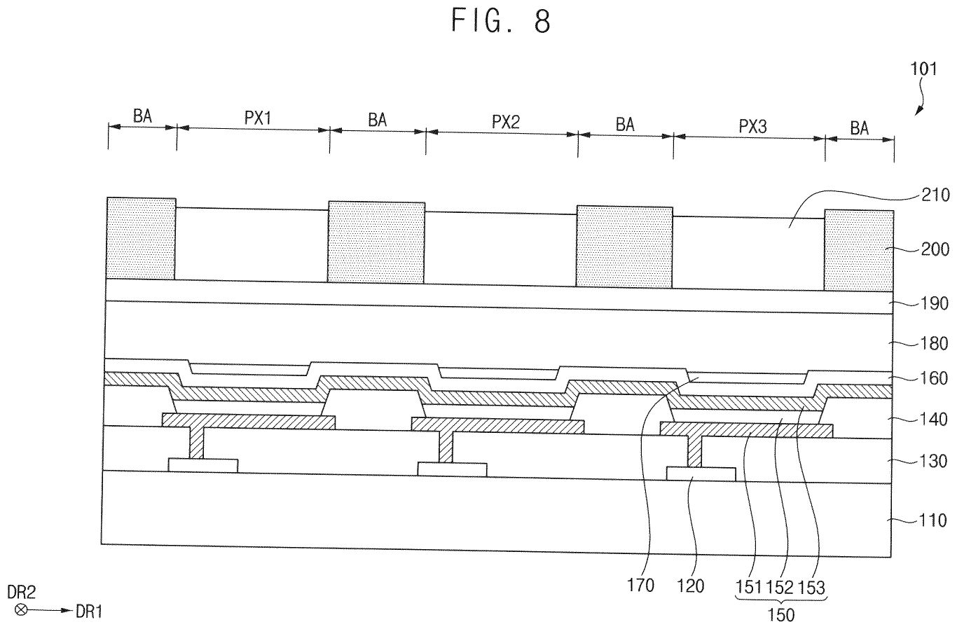

FIG. 8 is a cross-sectional view illustrating a display device according to another embodiment.

Referring to FIG. 8, a display device 101 according to an embodiment may include a substrate 110, a transistor 120, an insulating structure 130, a pixel defining layer 140, a light emitting element 150, a capping layer 160, a light absorption layer 170, an encapsulation layer 180, a sensing layer 190, a bank layer 200, and an anti-reflection layer 210. However, the display device 101 described with reference to FIG. 8 may be substantially the same as or similar to the display device 100 described with reference to FIG. 2 except for the configuration of the bank layer 200. Hereinafter, overlapping descriptions will be omitted.

The bank layer 200 may be disposed in the light blocking area BA on the sensing layer 190. For example, the bank layer 200 may include an inorganic material and/or an organic material.

In an embodiment, the bank layer 200 may not include scattering particles including an inorganic material. In this case, the bank layer 200 may further include a colorant such as an orange pigment, a violet pigment, a blue pigment, or the like. The bank layer 200 may not include a black pigment, a black dye, and the like.

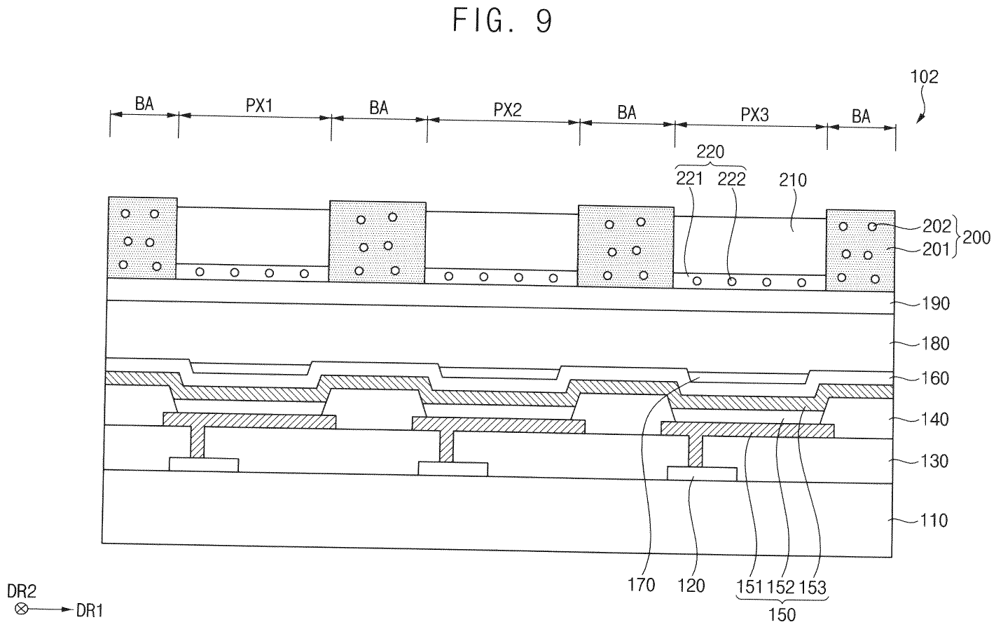

FIG. 9 is a cross-sectional view illustrating a display device according to still another embodiment.

Referring to FIG. 9, a display device 102 according to an embodiment may include a substrate 110, a transistor 120, an insulating structure 130, a pixel defining layer 140, a light emitting element 150, a capping layer 160, a light absorption layer 170, an encapsulation layer 180, a sensing layer 190, a bank layer 200, an anti-reflection layer 210, and a low refractive index layer 220. However, the display device 102 described with reference to FIG. 9 may be substantially the same as or similar to the display device 100 described with reference to FIG. 2, except that the low refractive index layer 220 is further included. Hereinafter, overlapping descriptions will be omitted.

The bank layer 200 may be disposed in the light blocking area BA on the sensing layer 190. The bank layer 200 may define openings overlapping the first, second, and third pixel regions PX1, PX2, and PX3, respectively, and exposing a portion of the sensing layer 190 in a plan view.

In an embodiment, the low refractive index layer 220 may be disposed in each of the first, second, and third pixel areas PX1, PX2, and PX3 on the sensing layer 190. For example, the low refractive index layer 220 may be disposed in at least one of the first, second, and third pixel areas PX1, PX2, and PX3. Specifically, the low refractive index layer 220 may be disposed inside the opening of the bank layer 200. The low refractive index layer 220 may have a relatively low refractive index.

In an embodiment, the low refractive index layer 220 may include a second base layer 221 and a plurality of second scattering particles 222 dispersed in the second base layer 221.

The second base layer 221 may include an inorganic material and/or an organic material. For example, the organic material may include an epoxy resin, a phenol resin, an acrylic resin, a silicone resin, or the like. These may be used alone or in combination with each other.

Each of the second scattering particles 222 may include an inorganic material. For example, the inorganic material may include titanium oxide, aluminum oxide, zirconium oxide, silicon oxide, or the like. These may be used alone or in combination with each other.

In an embodiment, the bank layer 200 may be formed in a process different from a process of the low refractive index layer 220. In another embodiment, the bank layer 200 may be formed in the same process as the low refractive index layer 220. That is, the bank layer 200 may be integrally formed (i.e., monolithic) with the low refractive index layer 220. In this case, the low refractive index layer 220 may include the same material as the bank layer 200.

The anti-reflection layer 210 may be disposed inside the opening of the bank layer 200. Specifically, the anti-reflection layer 210 may be disposed on the low refractive index layer 220.

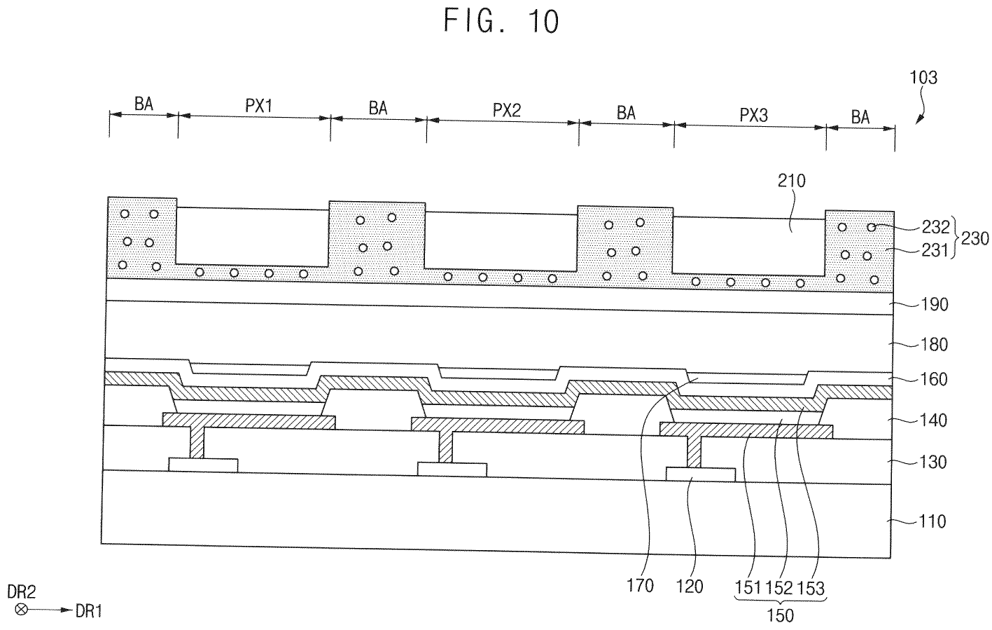

FIG. 10 is a cross-sectional view illustrating a display device according to still another embodiment.

Referring to FIG. 10, a display device 103 according to an embodiment may include a substrate 110, a transistor 120, an insulating structure 130, a pixel defining layer 140, a light emitting element 150, a capping layer 160, a light absorption layer 170, an encapsulation layer 180, a sensing layer 190, a bank layer 230, and an anti-reflection layer 210. However, the display device 102 described with reference to FIG. 10 may be substantially the same as or similar to the display device 100 described with reference to FIG. 2 except for the configuration of the bank layer 230. Hereinafter, overlapping descriptions will be omitted.

The bank layer 230 may be disposed on the sensing layer 190. The bank layer 230 may include a first portion overlapping the first, second, and third pixel areas PX1, PX2, and PX3 and a second portion overlapping the light blocking area BA in a plan view. A thickness of the second portion in the third direction DR3 may be greater than a thickness of the first portion. The bank layer 230 may be formed to include a halftone mask.

The bank layer 230 may include a first base layer 231 and a plurality of first scattering particles 232 dispersed in the first base layer 231.

The first base layer 231 may include an inorganic material and/or an organic material. In an embodiment, the first base layer 231 may include an organic material.

The first base layer 231 may further include alight blocking material such as a black pigment, a black dye, a carbon black, or the like. These may be used alone or in combination with each other. In another embodiment, the first base layer 231 may further include a colorant. For example, the book colorant may include an orange pigment, a violet pigment, a blue pigment, or the like. These may be used alone or in combination with each other.

The first scattering particles 232 may include an inorganic material. For example, the inorganic material may include titanium oxide, aluminum oxide, zirconium oxide, silicon oxide, or the like. These may be used alone or in combination with each other.

That is, when the bank layer 200 and the low refractive index layer 220 illustrated in FIG. 9 are integrally formed (i.e., monolithic), the bank layer 200 and the low refractive index layer 220 illustrated in FIG. 9 may correspond to the bank layer 230 illustrated in FIG. 10.

The present disclosure can be applied to various display devices. For example, the present disclosure is applicable to various display devices such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate;
a light emitting element disposed on the substrate;
an encapsulation layer disposed on the light emitting element;
a bank layer disposed on the encapsulation layer, defining an opening overlapping the light emitting element, and including a first base layer and a plurality of first scattering particles dispersed in the first base layer; and
an anti-reflection layer disposed inside the opening.

2. The display device of claim 1, wherein each of the first scattering particles includes an inorganic material.

3. The display device of claim 2, wherein the inorganic material includes at least one selected from a group consisting of titanium oxide (TiO₂), aluminum oxide (Al₂O₃), zirconium oxide (ZrO₂), and silicon oxide (SiO₂).

4. The display device of claim 1, wherein the first base layer includes an organic material or an inorganic material.

5. The display device of claim 4, wherein the first base layer further includes at least one selected from a group consisting of a carbon black, a black pigment, and a black dye.

6. The display device of claim 4, wherein the first base layer further includes at least one selected from a group consisting of an orange pigment, a violet pigment, and a blue pigment.

7. The display device of claim 1, wherein a refractive index of the bank layer is smaller than a refractive index of the anti-reflection layer.

8. The display device of claim 7, wherein the refractive index of the bank layer is about 1.2 to about 1.4.

9. The display device of claim 7, wherein the refractive index of the anti-reflection layer is about 1.5 to about 1.7.

10. The display device of claim 1, wherein the anti-reflection layer includes an inorganic material or an organic material.

11. The display device of claim 1, wherein the anti-reflection layer includes at least one selected from a group consisting of a pigment, a binder, and a monomer.

12. The display device of claim 1, further comprising:
a low refractive index layer disposed inside the opening,
wherein the anti-reflection layer is disposed on the low refractive index layer.

13. The display device of claim 12, wherein the low refractive index layer is monolithic with the bank layer.

14. The display device of claim 12, wherein the low refractive index layer includes a second base layer and a plurality of second scattering particles dispersed in the second base layer.

15. The display device of claim 14, wherein the second base layer includes an organic material or an inorganic material, and each of the second scattering particles includes an inorganic material.

16. The display device of claim 1, further comprising:
a capping layer disposed on the light emitting element; and
a light absorption layer disposed between the capping layer and the encapsulation layer and including an inorganic material.

17. A method for manufacturing a display device, the method comprising:
forming a light emitting element on a substrate;
forming an encapsulation layer on the light emitting element;
forming a bank layer defining an opening overlapping the light emitting element and including a first base layer and a plurality of first scattering particles dispersed in the first base layer on encapsulation layer; and
forming an anti-reflection layer inside the opening through an inkjet printing process.

18. The method of claim 17, wherein the first base layer includes an organic material or an inorganic material, and each of the first scattering particles includes an inorganic material.

19. The method of claim 18, wherein the first base layer further includes at least one selected from a group consisting of a carbon black, a black pigment, and a black dye.

20. The method of claim 17, wherein a refractive index of the bank layer is smaller than a refractive index of the anti-reflection layer.
